(19) United States
(12) Patent Application Publication
(10) Pub. No.: US 2019/0327840 A1
(43) Pub. Date: Oct. 24, 2019

(54) 3D INTERPOSER WITH THROUGH GLASS VIAS - METHOD OF INCREASING ADHESION BETWEEN COPPER AND GLASS SURFACES AND ARTICLES THEREFROM

(71) Applicant: Corning Incorporated, Corning, NY (US)

(72) Inventors: Dana Craig Bookbinder, Corning, NY (US); Yunfeng Gu, Painted Post, NY (US); Prantik Mazumder, Ithaca, NY (US); Rajesh Vaddi, Corning, NY (US)

(21) Appl. No.: 16/386,639

(22) Filed: Apr. 17, 2019

Related U.S. Application Data
(60) Provisional application No. 62/660,677, filed on Apr. 20, 2018.

(51) Int. Cl. H05K 3/38; H05K 3/18; H05K 3/00; H05K 3/42; H05K 1/03; H05K 1/11; H05K 1/09

(52) U.S. Cl. CPC H05K 3/381; H05K 3/181; H05K 3/002; H05K 3/422; H05K 2203/143; H05K 1/115; H05K 1/09; H05K 2203/0723; H05K 2203/1157; H05K 1/0306

(57) ABSTRACT

In some embodiments, a method comprises leaching a surface of a glass or glass ceramic substrate to form a leached layer. The glass or glass ceramic substrate comprises a multi-component material. The material has a bulk composition, in mol % on an oxide basis: 51% to 90% SiO₂; 10% to 49% total of minority components ROₓ. Leaching comprises selectively removing components ROₓ of the glass or glass ceramic substrate preferentially to removal of SiO₂. In the leached layer, the ROₓ concentration is 50% or less than the ROₓ concentration of the bulk composition.

This application claims the benefit of priority to U.S. Provisional Application Ser. No. 62/660,677 filed on Apr. 20, 2018, the content of which is relied upon and incorporated herein by reference in its entirety.

### FIELD

This description pertains to glass surfaces and articles having improved adhesion to copper.

### BACKGROUND

Glass and glass ceramic substrates with vias are desirable for many applications, including for use as in interposers used as an electrical interface, RF filters, and RF switches. Glass substrates have become an attractive alternative to silicon and fiber reinforced polymers for such applications. But, it is desirable to fill such vias with copper, and copper does not adhere well to glass. In addition, a hermetic seal between copper and glass is desired for some applications, and such a seal is difficult to obtain because copper does not adhere well to glass.

Accordingly, a need exists for methods of better adhering copper to glass and glass ceramic materials.

### SUMMARY

In a first embodiment, a method comprises leaching a surface of a glass or glass ceramic substrate to form a leached layer. The glass or glass ceramic substrate comprises a multi-component material. The material has a bulk composition, in mol % on an oxide basis: 51% to 90% SiO₂; 10% to 49% total of minority components ROₓ. Leaching comprises selectively removing components ROₓ of the glass or glass ceramic substrate preferentially to removal of SiO₂. In the leached layer, the ROₓ concentration is 50% or less than the ROₓ concentration of the bulk composition.

In a second embodiment, the first embodiment further comprises etching the surface. Etching comprises selectively removing SiO₂ from the substrate preferentially to removal of minority components ROₓ.

In a third embodiment, the second embodiment further comprises leaching the surface before etching the surface.

In a fourth embodiment, the second embodiment further comprises leaching the surface after etching the surface.

In a fifth embodiment, for the method of the first embodiment, after leaching, the surface has a surface roughness Ra of 0.3 nm or more, and the leached layer has a thickness of 100 nm or more.

In a sixth embodiment, for the method of any of the second through fourth embodiments, after leaching and etching, the surface has a surface roughness Ra of 0.4 nm or more, and the leached layer has a thickness of 20 nm or more.

In a seventh embodiment, for the method of any of the second through fourth embodiments, after leaching and etching, the surface has a surface roughness Ra of 0.5 nm or more, and the leached layer has a thickness of 20 nm or more.

In an eighth embodiment, for the method of any of the second through fourth embodiments, after leaching and etching, the surface has a surface roughness Ra of 1 nm or more, and the leached layer has a thickness of 50 nm or more.

In a ninth embodiment, for the method of any of the first through fourth embodiments, the leached layer has a thickness of 20 nm or more.

In a tenth embodiment, for the method of any of the first through fourth embodiments, the leached layer has a thickness of 50 nm or more.

In an eleventh embodiment, for the method of any of the first through fourth embodiments, the leached layer is nanoporous layer.

In a twelfth embodiment, for the method of the eleventh embodiments, the nanoporous layer comprises pores having a size of 2-8 nm.

In a thirteenth embodiment, for the method of any of the first through twelfth embodiments, the leached layer has a re-entrant geometry.

In a fourteenth embodiment, for the method of any of the first through thirteenth embodiments the surface is an interior surface of a via formed in the glass or glass ceramic substrate.

In a fifteenth embodiment, for the method of the fourteenth embodiment, the via is a through via.

In a sixteenth embodiment, for the method of the fourteenth embodiment, the via is a blind via.

In a seventeenth embodiment, the method of any of the first through sixteenth embodiments further comprises depositing electroless copper onto the surface, and depositing electroplated copper over the electroless copper.

In an eighteenth embodiment, the method of the seventeenth embodiment further comprises charging the leached layer by treating with aminosilanes or nitrogen-containing polycations. After charging, palladium complexes are adsorbed into the leached layer by treatment with a palladium-containing solution. Depositing electroless copper into the leached layer and onto the surface occurs after adsorbing.

In a nineteenth embodiment, for the method of any of the seventeenth and eighteenth embodiments, the electroplated copper is capable of passing a 3N/cm tape test after being annealed at 350° C. for 30 minutes.

In a twentieth embodiment, for the method of any of the first through nineteenth embodiments, ROₓ is selected from Al₂O₃, B₂O₃, MgO, CaO, SrO, BaO, and combinations thereof.

In a twenty first embodiment, for the method of any of the first through twentieth embodiments, the material has a bulk composition, in mol % on an oxide basis:
SiO₂: 64.0-71.0
Al₂O₃: 9.0-12.0
B₂O₃: 7.0-12.0
MgO: 1.0-3.0
CaO: 6.0-11.5
SrO: 0-2.0
BaO: 0-0.1

In a twenty second embodiment, for the method of any of the first through twenty first embodiments, leaching comprises exposing the surface to a solution consisting essentially of hydrochloric acid, sulfuric acid, nitric acid and combinations thereof.

In a twenty third embodiment, for the method of any of the second through twenty second embodiments, etching comprises exposing the surface to an etchant selected from: a solution comprising hydrofluoric acid and hydrochloric acid, and a solution comprising tetramethylammonium hydroxide (TMAH).

In a twenty fourth embodiment, an article comprises a glass or glass ceramic substrate having a plurality of vias formed therein, each via having an interior surface. The glass or glass ceramic substrate comprises a multi-component material, the material having a bulk composition, in mol % on an oxide basis: 51% to 90% SiO₂, and 10% to 49% total of minority components ROₓ. A leached layer is formed under the interior surfaces of the vias. In the leached layer, the ROₓ concentration is 50% or less than the ROₓ concentration of the bulk composition. The leached layer has a thickness of 1 nm or more.

In a twenty fifth embodiment, for the article of the twenty fourth embodiment, the via is empty.

In a twenty sixth embodiment, the article of the twenty fourth embodiment further comprises copper filling the via.

In a twenty seventh embodiment, for the article of the twenty sixth embodiment, the copper filling the via is capable of passing a 3N/cm tape test after being annealed at 350° C. for 30 minutes.

In a twenty eighth embodiment, for the article of the twenty fourth through twenty seventh embodiments, the interior surface is an etched surface.

In a twenty ninth embodiment, for the article of the twenty fourth embodiment, the interior surface has a surface roughness Ra of 0.3 nm or more, and the leached layer has a thickness of 100 nm or more.

In a thirtieth embodiment, for the article of the twenty ninth embodiment, the interior surface has a surface roughness Ra of 0.4 nm or more, and the leached layer has a thickness of 20 nm or more.

In a thirty first embodiment, for the article of the thirtieth, the interior surface has a surface roughness Ra of 0.5 nm or more, and the leached layer has a thickness of 20 nm or more.

In a thirty second embodiment, for the article of the thirtieth embodiment, the interior surface has a surface roughness Ra of 1 nm or more, and the leached layer has a thickness of 50 nm or more.

In a thirty third embodiment, for the article of any of the twenty fourth through twenty eighth embodiments, the leached layer has a thickness of 20 nm or more.

In a thirty fourth embodiment, for the article of the thirty third embodiment, the leached layer has a thickness of 50 nm or more.

In a thirty fifth embodiment, for the article of the twenty fourth through thirty fourth embodiments, the leached layer is nanoporous layer.

In a thirty sixth embodiment, for the article of the thirty fifth embodiment, the nanoporous layer comprises pores having a size of 2-8 nm.

In a thirty seventh embodiment, for the article of the twenty fourth through thirty sixth embodiments, the leached layer has a re-entrant geometry.

In a thirty eighth embodiment, for the article of the twenty fourth through thirty seventh embodiments, the via is a through via.

In a thirty ninth embodiment, for the article of the twenty fourth through thirty seventh embodiments, wherein the via is a blind via.

In a fortieth embodiment, for the article of the twenty fourth through thirty ninth embodiments, ROₓ is selected from Al₂O₃, B₂O₃, MgO, CaO, SrO, BaO, and combinations thereof.

In a forty first embodiment, for the article of the twenty fourth through forty first embodiments, the material has a bulk composition, in mol % on an oxide basis:
SiO₂: 64.0-71.0
Al₂O₃: 9.0-12.0
B₂O₃: 7.0-12.0
MgO: 1.0-3.0
CaO: 6.0-11.5
SrO: 0-2.0
BaO: 0-0.1

### BRIEF DESCRIPTION OF THE DRAWINGS

FIG. 1 shows a substrate having through vias.

FIG. 2 shows a substrate having blind vias.

FIG. 3 shows a flowchart for a process of leaching then etching a surface, then depositing copper onto the surface.

FIG. 4 shows region 400 of FIG. 1 as it appears at different steps of the flowchart of FIG. 3.

FIG. 5 shows a flowchart for a process of etching then leaching a surface, then depositing copper onto the surface.

FIG. 6 shows region 400 of FIG. 1 as it appears at different steps of the flowchart of FIG. 5.

FIG. 7 shows a schematic of mechanical interlocking of Pd catalyst and electroless Cu.

FIG. 8 shows an AFM surface morphology of three glass samples, comparing the effect of different etching treatments.

FIG. 9 shows a SIMS (Secondary Ion Mass Spectrometry) profile for aluminum element of a glass sample leached with 0.15 M HCl at 75° C. for 2, 30, and 240 minutes, respectively.

FIG. 10 shows SEM images comparing surface morphologies of an unleached control samples, and samples leached with 0.15 M HCl at 75° C. for 4 hrs and 18 hrs.

FIG. 11 shows an SEM (Scanning Electron Microscope) image and EDS (Energy Dispersive Spectroscopy) analysis of glass leached with 0.15 M HCl solution at 75° C. for 2 h.

FIG. 12 shows a SIMS profile for five elements (B, Mg, Al, Si, and Ca) of a glass sample leached with 0.15 M HCl at 95° C. for 6 hours. The depth of the leaching layer is 237 nm based on the Al element profile.

FIG. 13 shows cross-sectional images of glass leached with 0.15 M HCl at 95° C. for 6 hours. The depth of the leaching layer is 279 nm. The high resolution image shows that the leaching layer is nanoporous layer with pore size in the range of 2-8 nm.

FIG. 14 shows cross-sectional SEM/EDS image of a glass sample that was leached with 0.15 M HCl at 95° C. for 6 hours followed by etching with 5% TMAH solution at 60° C. for 10 minutes.

FIG. 15 shows AFM surface morphology of six glass samples: a) control without leaching/etching; b) leached at 95° C. for 6 h; c) leached followed by TMAH etching at 40° C. for 30 minutes; d) leached followed by TMAH etching at 60° C. for 2 minutes; e) leached followed by TMAH etching at 60° C. for 10 minutes; and (f) leached followed by TMAH etching at 60° C. for 30 minutes.

FIG. 16 shows TEM (Transmission Electron Microscope)/EDS images of cross-section of one sample in Example 4 which had sandwich structure with nanoporous leaching layer between copper film and glass substrate. The presence of Pd and Cu inside the leaching layer is clearly demonstrated.

FIG. 17 shows schematics of various surface morphologies that illustrate the concept of re-entrant geometry.

### DETAILED DESCRIPTION

Glass and glass ceramic substrates with vias are desirable for a number of applications. For example, 3D interposers with through package via (TPV) interconnects that connect the logic device on one side and memory on the other side are desirable for high bandwidth devices. The current substrate of choice is organic or silicon. Organic interposers suffer from poor dimensional stability while silicon wafers are expensive and suffer from high dielectric loss due to semiconducting property. Glass may be a superior substrate material due to its low dielectric constant, thermal stability, and low cost. There are applications for glass or glass ceramic substrates with through vias or blind vias. These vias typically need to be fully or conformally filled by conducting metals such as copper to provide an electrical pathway. Copper is a particularly desirable conducting metal. The chemical inertness and low intrinsic roughness of glass and glass ceramic materials, however, pose a problem related to adhesion of the copper to the glass wall inside the vias. Lack of adhesion between copper and glass could lead to reliability issues such as cracking, delamination, and a path for moisture and other contaminants along the glass-copper interface. Described herein are approaches to increase the effective adhesion between copper and glass or glass ceramic materials on any glass or glass ceramic surface, including the interior surface of vias as well as other surfaces.

In some embodiments, the effective adhesion between copper and glass or glass ceramic may be increased through glass surface treatment such as leaching, or a combination of leaching and etching. It has been discovered that acid leaching can generate a nanoporous layer on the surface both inside the vias and on the planar surface, which has interconnected porosity and thus allows better mechanical interlock. It has been discovered that a combination of leaching and etching leads to higher surface roughness than leaching alone, while still preserving the nanoporous layer created by leaching. It has also been discovered that a combination of leaching followed by etching is surprisingly effective at forming of nanoporous layer with an open surface microstructure and rougher surface. Both the nanoporous layer and higher surface roughness are believed to increase copper adhesion due to mechanical interlocking between copper and the glass or glass ceramic.

In some embodiments, copper is deposited using electroless deposition, or electroless deposition followed by electroplating. Electroless deposition often involves the use of a catalyst, such as Pd. For this type of electroless deposition of copper onto glass, the copper typically does not form a chemical bond to the glass, and instead relies on mechanical interlocking and surface roughness for adhesion. In some embodiments, this mechanical interlocking is achieved by creating rough structure in the glass or glass ceramic substrate with re-entrant geometries. Penetration of catalyst into the re-entrant geometry promotes deposition of electroless copper throughout the re-entrant geometry, which leads to good mechanical interlocking. One example of a re-entrant geometry is an interconnected nanoporous structure.

Substrates with Vias

As used herein, a “via” is an opening in a substrate. A via may extent all the way through the substrate, in which case it is a “through via.” A via may extend only partially through the substrate, in which case it is a “blind via.”

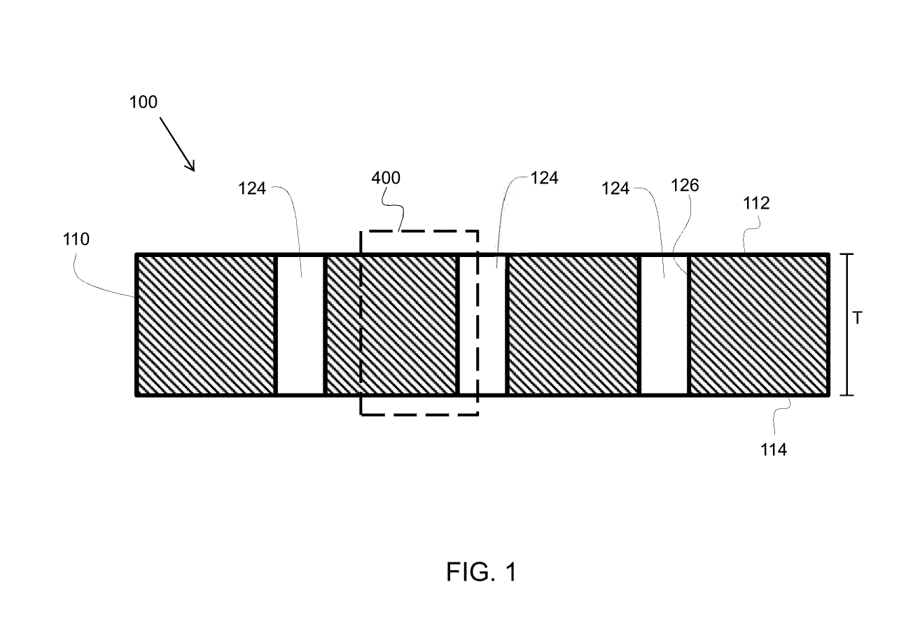

FIG. 1 shows a cross section of an example article 100. Article 100 includes a substrate 110. Substrate 110 has a first surface 112 and a second surface 114, separated by a thickness T. A plurality of vias 124 extend from first surface 112 to second surface 114, i.e., vias 124 are through vias. Interior surface 126 is the interior surface of via 124 formed in substrate 110.

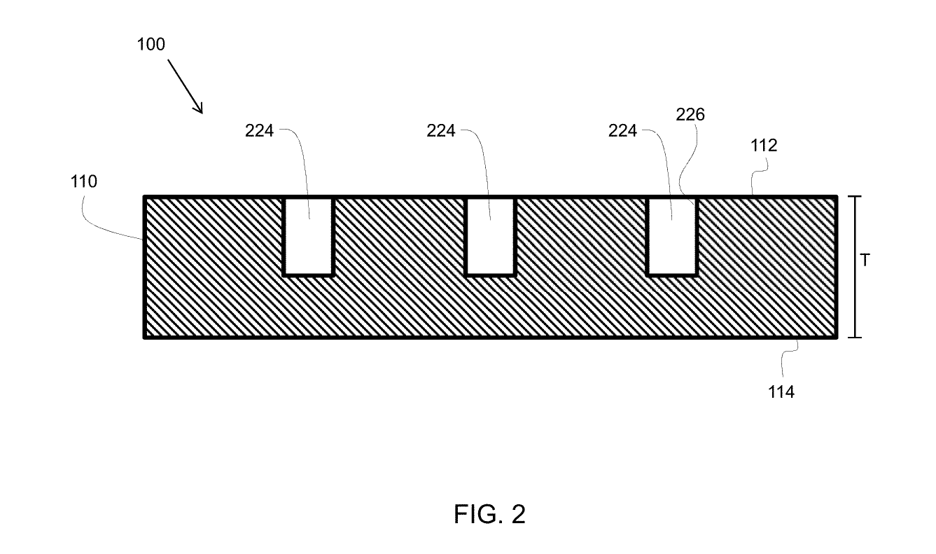

FIG. 2 shows a cross section of an example article 200. Article 200 includes a substrate 110. Substrate 110 has a first surface 112 and a second surface 114, separated by a thickness T. A plurality of vias 224 extend from first surface 112 towards second surface 114, without reaching second surface 114, i.e., vias 124 are blind vias. Surface 226 is the interior surface of via 224 formed in substrate 110.

While FIGS. 1 and 2 show specific via configurations, various other via configurations may be used. By way of non-limiting example, vias having an hourglass shape, a barbell shape, beveled edges, or a variety of other geometries may be used instead of the cylindrical geometries shown in FIGS. 1 and 2. The via may be substantially cylindrical, for example having a waist (point along the via with the smallest diameter) with a diameter that is at least 70%, at least 75%, or at least 80% of the diameter of an opening of the via on the first or second surface. The via may have any suitable aspect ratio. For example, the via may have an aspect ratio of 1:1, 2:1, 3:1, 4:1, 5:1, 6:1, 7:1, 8:1, 9:1, 10:1, or any range having any two of these values as endpoints, or any open-ended range having any of these values as a lower bound. Other via geometries may be used.

### Surface Roughness

First surface 112 and second surface 114 have a pre-etch surface roughness (Ra). As used herein, “surface roughness” refers to arithmetic mean surface roughness. The literature often uses the notation “Ra” to arithmetic mean surface roughness. Surface roughness Ra is defined as the arithmetic average of the differences between the local surface heights and the average surface height, and can be described by the following equation:

$${R}_{a} = \frac{1}{n} {\sum }_{i = 1}^{n} \vert {y}_{i} \vert$$

where yᵢ is the local surface height relative to the average surface height. Surface roughness (Ra) may be measured and/or calculated from measurements using a variety of techniques. Unless otherwise specified, surface roughness as described herein is measured using a Veeco Dimension Icon atomic force microscope (AFM) with the following parameters: 1 Hz, 512 scans/line, and 2 micron image size.

### Nano-Porosity

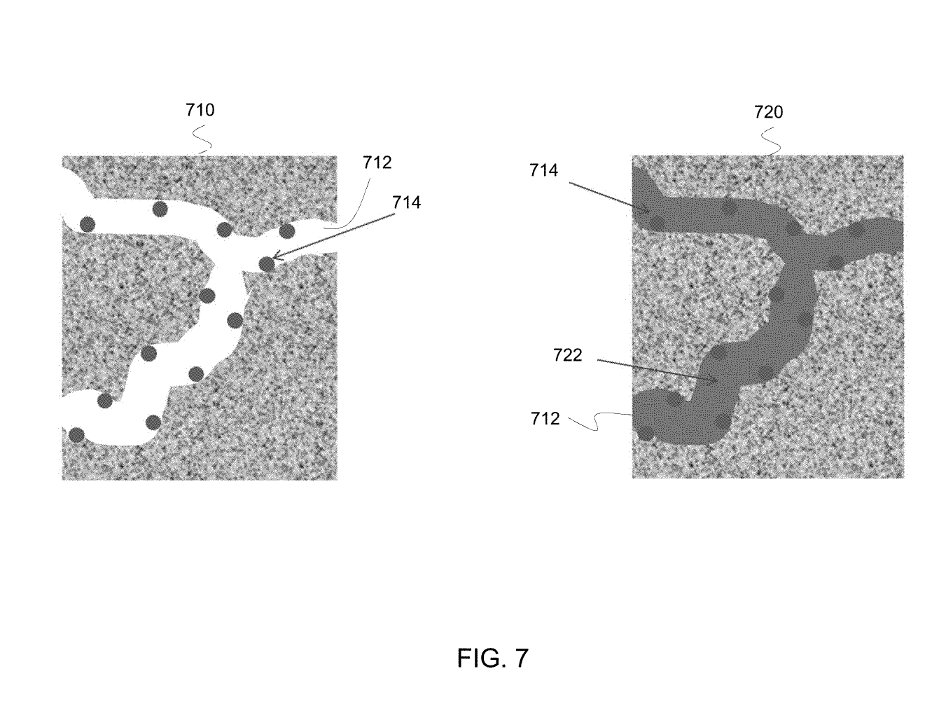

As used herein, a “nanoporous layer” has a porous structure, where the size of the pores is 100 nm or less. A nanoporous structure as used herein comprises a plurality of interconnected tunnels or “nanopores.” The nanoporous structures described herein are generally open structures, in that there is a path of travel from anywhere within a nanopore to the surface of the material. The nanoporous structures are open because of the manner in which they are formed—the leachant penetrates deeper into the material through the nanoporous layer as it is formed. While the nanoporous layers described herein are generally interconnected, it is possible that portions of the nanoporous network may be isolated from each other. Nano-pore 712 of FIG. 7 is an example of a nanopore.

The “size” of a nanopore is the average dimension of a cross-section of the pore in a plane normal to the direction of the pore. So, if a cylindrical nanopore intersects a surface, the “size” of the nanopore is the diameter of the circle. For non-circular cross sections, the “size” of the cross-section is the diameter of a circle having the same area as the cross-section. Nanopore size is measured by obtaining a high-resolution SEM image, measuring the area of all visible nanopores in a 100×100 nm area, calculating the diameter of a circle with equivalent area, and calculating the average of these diameters. Where the nanopores are circular in shape, the same result may be obtained by directly measuring the diameter. In some embodiments, the size of the nano-pores are 2 nm to 10 nm, or 2 nm to 8 nm. In some embodiments, the size of the nanopores is 0.5, 1, 2, 3, 4, 5, 6, 7, 8, 9, 10, 11 or 12 nm, or any range having any two of these values as endpoints.

### Composition

In the most general sense, any glass or glass-ceramic composition having 51% or more SiOₓ may be used, i.e., the original (prior to leaching) bulk composition is:
SiO₂ content: 51% to 90%
ROₓ content: 10% to 49%.

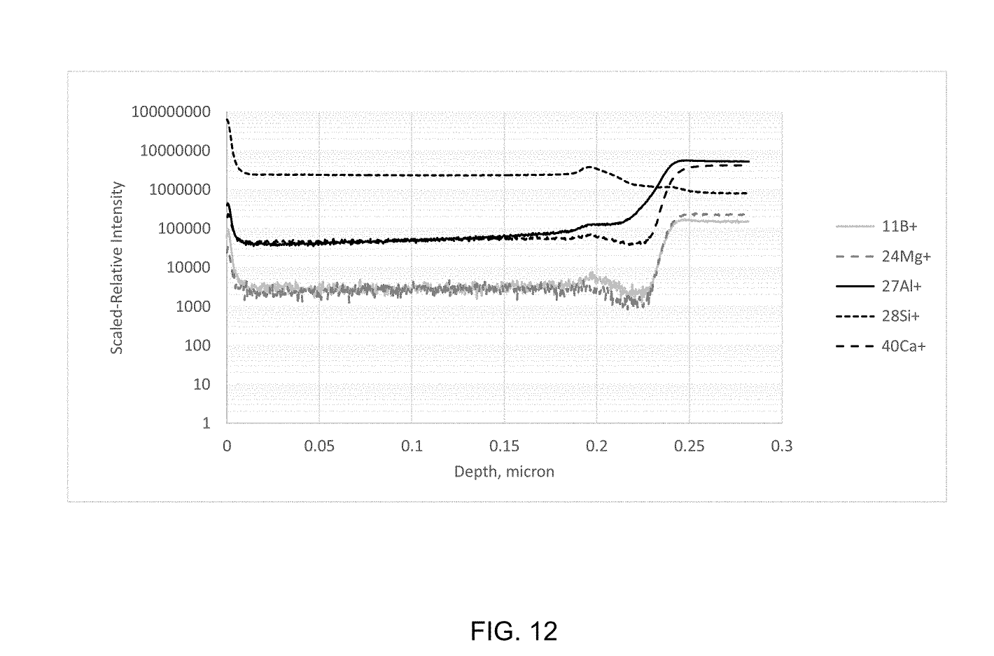

As used herein, “bulk composition” refers to the composition of a material prior to any leaching or etching. Where leaching or etching preferentially removes some components of a material relative to others, there is a deviation from bulk composition in the leached or etched area. In a SIMS plot, such as that of FIG. 12, the values measured at depths greater than those affected by leaching and/or etching reflect the bulk composition. For example, in FIG. 12, the values at depths greater than 0.25 microns reflect the bulk composition. Percentages of compositions herein are provided as mol % on an oxide basis. In some embodiments, to enhance the structural integrity of the framework of majority-component material remaining after leaching minority components ROₓ, while also having an amount of ROₓ sufficient to generate a robust nanoporous network when leached, the original bulk SiO₂ content is 55% to 80% and the minority components ROₓ comprise 20% to 45%, or the original bulk SiO₂ content is 64% to 71%, and the minority components ROₓ comprise 29% to 36% of the bulk composition.

In some embodiments, Al₂O₃ is one of the minority components ROₓ, and Al₂O₃ is the component having the highest mol % on an oxide basis after SiO₂.

In some embodiments, minority components ROₓ are selected from from Al₂O₃, B₂O₃, MgO, CaO, SrO, BaO, and combinations thereof. The leachants described herein remove each of these components at a rate significantly higher than the rate at which they remove SiO₂.

In some embodiments, the material has a bulk composition, in mole percent on an oxide basis:
SiO₂: 64.0-71.0
Al₂O₃: 9.0-12.0
B₂O₃: 7.0-12.0
MgO: 1.0-3.0
CaO: 6.0-11.5
SrO: 0-2.0 (preferably 0-1.0)
BaO: 0-0.1

(Composition 1).

For the compositions described above, the etchants described herein remove SiO₂ at a rate higher than that at which they remove the other components. And, the leachants described herein remove each of the ROₓ components (components other than SiO₂) at about the same rate, which is significantly higher than the rate at which the leachants remove SiO₂. The amount of SiO₂ remaining after the other components have been leached is sufficient to form a robust framework. And, the amount of ROₓ components is sufficient to form a nanoporous layer when leached.

### Leaching

“Leaching” as used herein means selectively removing minority components ROₓ of the glass substrate preferentially to removal of SiO₂. Leaching occurs when a leaching agent, such as an acid, removes the minority components ROₓ at a faster rate than SiO₂. As a result, the percentage of ROₓ removed, compared to the amount of SiO₂, is greater than would be expected if all components were removed at a rate proportionate to the amount of component in the composition.

As used herein, a “leached layer” refers to a layer in which the ROₓ concentration is 50% or less than the ROₓ concentration of the bulk composition due to preferential removal with a leaching agent of the ROₓ component from the leached layer compared to removal of SiO₂. Due to the way it is formed, a leached layer has unique structural characteristics when compared, for example, to a layer having the same composition as the leached layer, but formed by a different method. Compared to the bulk composition, ROₓ has been removed from the leached layer. The SiO₂ and reduced amount ROₓ components that remain retain the microstructure from the bulk composition, with spaces or pores where the leached ROₓ was removed. For the compositions described herein, such as Composition 1, leaching generally results in a leached layer having a nanoporous structure with a re-entrant geometry.

Directly measuring the ROₓ concentration to see whether it is 50% or less than the ROₓ concentration of the bulk composition by SIMS analysis involves measuring each ROₓ component by SIMS. Unless otherwise specified, this is how ROₓ concentration is measured. But, the inventors have determined that, for the compositions and leachants described herein, each of the ROₓ components leach at about the same rate. This is illustrated, for example, in FIG. 12. So, measuring the concentration of one of the ROₓ components, preferably one with a relatively high concentration (7 wt % or more on an oxide basis), provides a reasonable measure of the concentration of the other ROₓ components. As a result, measurements of the aluminum profile by SIMS described herein are a good measure of the ROₓ profile.

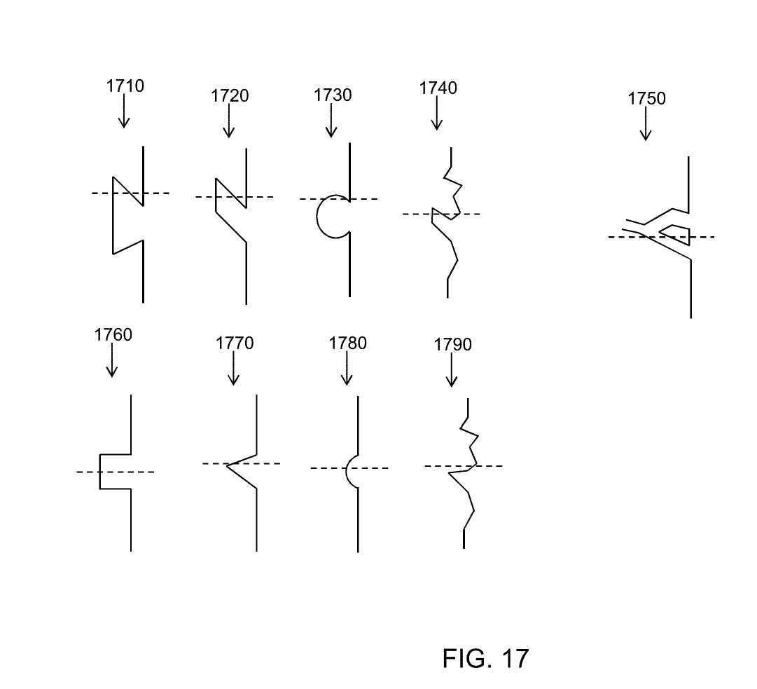

As used herein, a “reentrant geometry” refers to a surface geometry where there is at least one line perpendicular to a major surface that crosses the surface of the material more than once. A “major surface” of a material is the surface on a macroscopic scale—the surface defines by a plane that rests on, but does not intersect, the material. For a reentrant geometry, there is at least one line that enters the material, exits the material (into an open nanopore, for example), and reenters the material. Where the reentrant geometry is filled, for example, with copper, even if the copper is not bonded to the material, mechanical interlocking prevents pulling the copper straight out without deforming the copper or the material. A rough surface may or may not be reentrant. A nanoporous surface will almost always be reentrant, although the unlikely case of cylindrical pores, not interconnecting and all aligned perpendicular to the surface, is not reentrant. FIG. 17 shows some examples of surface geometries that are reentrant (surface 1710, surface 1720, surface 1730, surface 1740 and surface 1750), and surface geometries that are not reentrant (surface 1760, surface 1770, surface 1780 and surface 1790). In each of the surfaces of FIG. 17, air is to the right, and substrate material is to the left. Moving from right to left, the dotted line normal to the major surface always moves from air into substrate material, for both reentrant and non-reentrant surfaces. But, for the reentrant surfaces, the dotted line moves from air to substrate material, then back to air, then back to substrate material. Surface 1750 is an example of a reentrant nanoporous surface geometry. FIG. 7 also illustrates a reentrant nanoporous surface geometry.

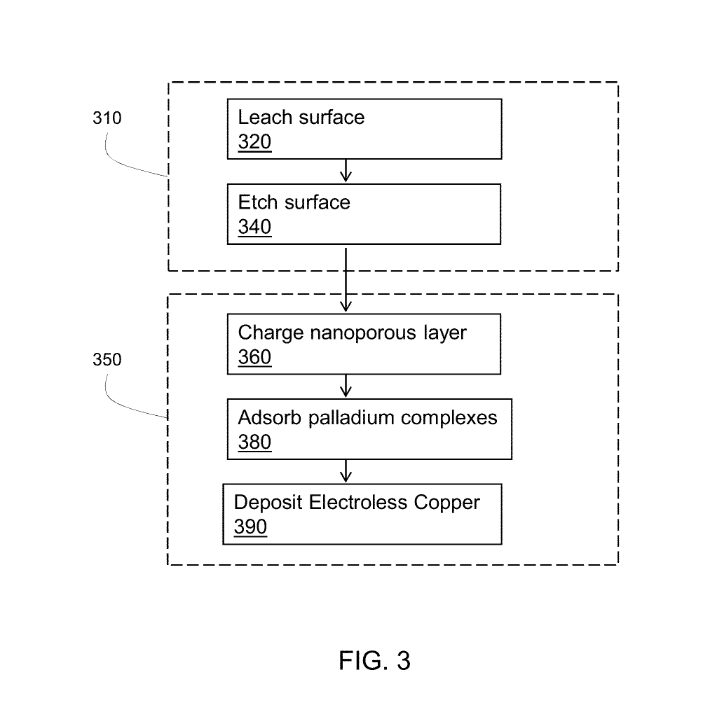

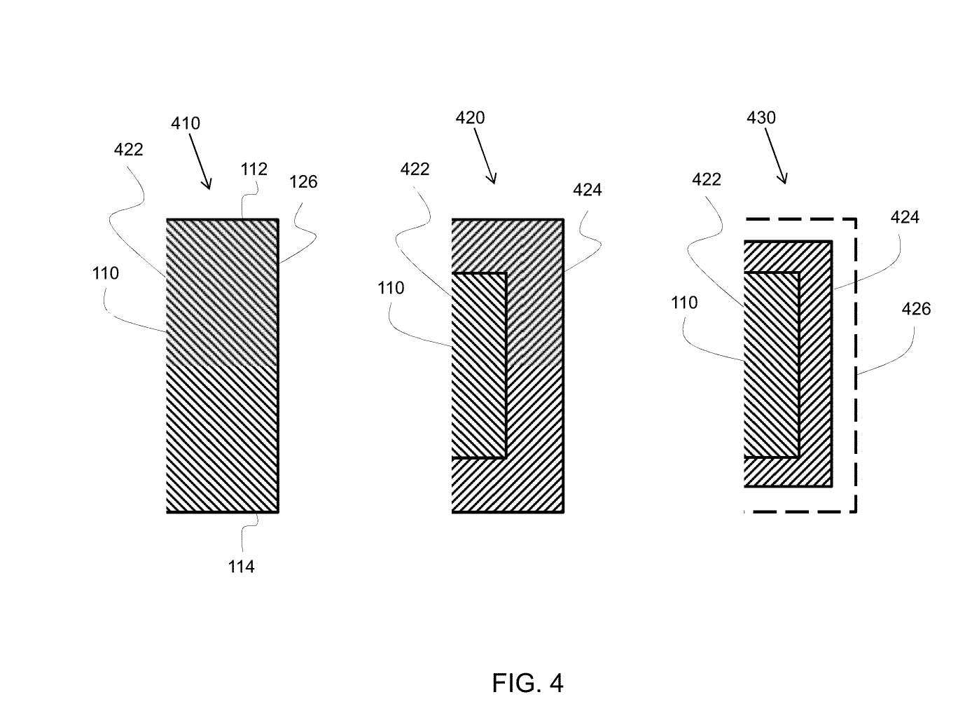

In some embodiments, a substrate is subject to leaching but not etching before being metallized. Such a process is illustrated, for example, in FIGS. 3 and 4 and the related discussion, but with the etching step removed.

In some embodiments, where a substrate is subject to leaching but not etching before being metallized, after leaching the substrate has a surface roughness Ra of 0.1 nm, 0.2 nm, 0.3 nm, 0.4 nm, 0.5 nm or any range having any two of these values as endpoints, or any open-ended range having any of these values as a lower bound. In some embodiments, after leaching the substrate has a surface roughness of 0.3 nm or more, or 0.3 nm to 0.5 nm.

In some embodiments, where a substrate is subject to leaching but not etching before being metallized, after leaching the substrate has a leached layer with a thickness of 1 nm, 5 nm, 10 nm, 20 nm, 40 nm, 50 nm, 60 nm, 80 nm, 100 nm, 150 nm, 200 nm, or any range having any two of these values as endpoints, or any open-ended range having any of these values as a lower bound. In some embodiments, the leached layer has a thickness of 100 nm or more, or 100 nm to 200 nm.

In some embodiments, where a substrate is subject to leaching but not etching before being metallized, after leaching the substrate has any of the ranges described above for surface roughness Ra combined with any of the ranges described above for leached layer thickness. In some embodiments, the substrate has a surface roughness of 0.3 nm or more, or 0.3 nm to 0.5 nm, combined with a leached layer of 100 nm or more, or 100 nm to 200 nm.

In some embodiments as illustrated herein, all surfaces of a substrate are exposed to leachant. But, in some embodiments, selected surfaces the substrate may be protected from exposure to leachant, for example by photoresist or other protective layer, in which case the selected surfaces would not be leached.

### Etching

“Etching” as used herein means selectively removing majority component A of the glass substrate preferentially to the removal of minority components B. The etchants used to preferentially remove majority component A can and often do also remove minority components B, but at a rate slower than they remove majority component A. Minority components B are generally removed along with majority component A during etching, as minority components B are quite exposed to etchant and have limited structural integrity once majority component A is removed.

In some embodiments as illustrated herein, all surfaces of a substrate are exposed to etchant. But, in some embodiments, selected surfaces the substrate may be protected from exposure to etchant, for example by photoresist or other protective layer, in which case the selected surfaces would not be etched.

A glass surface that has been etched has distinctive structural characteristics, and one of skill in the art can tell from inspecting a glass surface whether that surface has been etched. Etching often changes the surface roughness of the glass. So, if one knows the source of the glass and the roughness of that source, a measurement of surface roughness can be used to determine whether the glass has been etched. In addition, etching generally results in differential removal of different materials in the glass. This differential removal can be detected by techniques such as electron probe microanalysis (EPMA). Moreover, in the case of previously leached surfaces, etching may remove a portion of the leached layer, as described herein, which is another structural difference between etched and un-etched layers.

### Leaching Followed by Etching

FIG. 3 shows a flowchart for a process in accordance with some embodiments. First, a substrate is prepared for metallization in process flow 310. Then, the substrate may optionally be metallized in process flow 350. FIG. 4 illustrates what the substrate looks like during process flow 310. Specifically, FIG. 4 shows region 400 of FIG. 1. Although FIG. 4 shows a specific substrate geometry, any substrate geometry for which metallization is desired may be used.

Process flow 310 shows steps for preparing substrate 110 for metallization. Schematic 410 shows substrate 110 prior to leaching and/or etching. Region 422, which is the whole substrate in schematic 410, has the bulk composition of substrate 110.

In step 320, substrate 110 is leached. As illustrated in FIG. 4, first surface 112, second surface 114 and interior surface 126 are exposed to leachant and leached. Schematic 420 shows substrate 110 after leaching. A leached layer 424 has been formed due to leaching. Region 422, which has the bulk composition of substrate 110, has correspondingly shrunk. As will become clear from the examples, there is a small part of region 422 next to leached layer 424 that has been subject to some leaching, but not enough to qualify as a “leached layer” as defined herein. Substrate 110 is illustrated as having about the same size in schematic 410 and schematic 420, because leaching primarily removes material from within leached layer 424 to modify the substrate composition, while leaving the shape and size of substrate 110 relatively the same.

In step 340, substrate 110 is etched after having been leached in step 320. The etchant and etching parameters are selected to remove some, but not all, of leached layer 424. Schematic 430 shows substrate 110 after etching. Region 422 remains similar to how it appeared after step 320. A part of leached layer 424 has been removed by etching. Dotted line 426 shows the extent of substrate 110 (and leached layer 424) prior to etching. Substrate 110 is illustrated as being smaller in schematic 430 than schematic 420, because etching primarily results in the removal of a layer as opposed to modifying the composition of substrate 110.

In some embodiments, where a substrate is subject to leaching followed by etching before being metallized, after leaching and etching the substrate has a surface roughness Ra of 0.1 nm, 0.2 nm, 0.3 nm, 0.4 nm, 0.5 nm, 0.6 nm, 0.7 nm, 0.8 nm, 0.9 nm, 1.0 nm, or any range having any two of these values as endpoints, or any open-ended range having any of these values as a lower bound. In some embodiments, after leaching and etching the substrate has a surface roughness of 0.4 nm or more, 0.4 nm to 1.0 nm, 0.5 nm or more, 0.5 nm to 1.0 nm, or 1 nm or more.

In some embodiments, where a substrate is subject to leaching followed by etching before being metallized, after leaching and etching the substrate has a leached layer with a thickness of 1 nm, 5 nm, 10 nm, 20 nm, 40 nm, 50 nm, 60 nm, 80 nm, 100 nm, 150 nm, 200 nm, or any range having any two of these values as endpoints, or any open-ended range having any of these values as a lower bound. In some embodiments, the leached layer has a thickness of 20 nm or more, 20 nm to 200 nm, 50 nm or more, or 50 nm to 200 nm. The thickness of the leached layer in this case is that of the leached layer remaining after etching.

In some embodiments, where a substrate is subject to leaching followed by etching before being metallized, after leaching and etching the substrate has any of the ranges described above for surface roughness Ra combined with any of the ranges described above for leached layer thickness. In some embodiments, after leaching and etching the substrate has a surface roughness of 0.4 nm or more, 0.4 nm to 1.0 nm, 0.5 nm or more, 0.5 nm to 1.0 nm, or 1 nm or more, combined with a thickness of 20 nm or more, 20 nm to 200 nm, 50 nm or more, or 50 nm to 200 nm.

After leaching followed by etching, substrate 110 may optionally be metallized by any suitable method. One such method is illustrated in FIG. 3.

### Etching Followed by Leaching

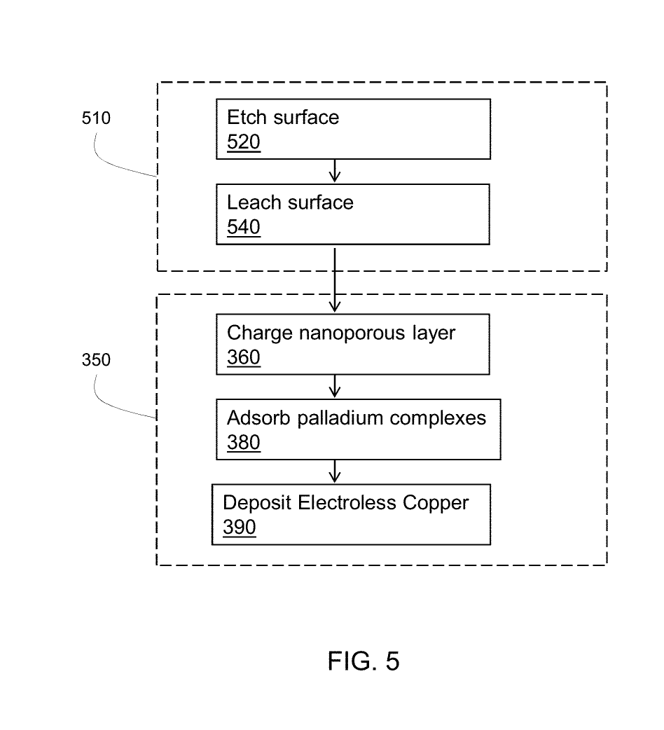

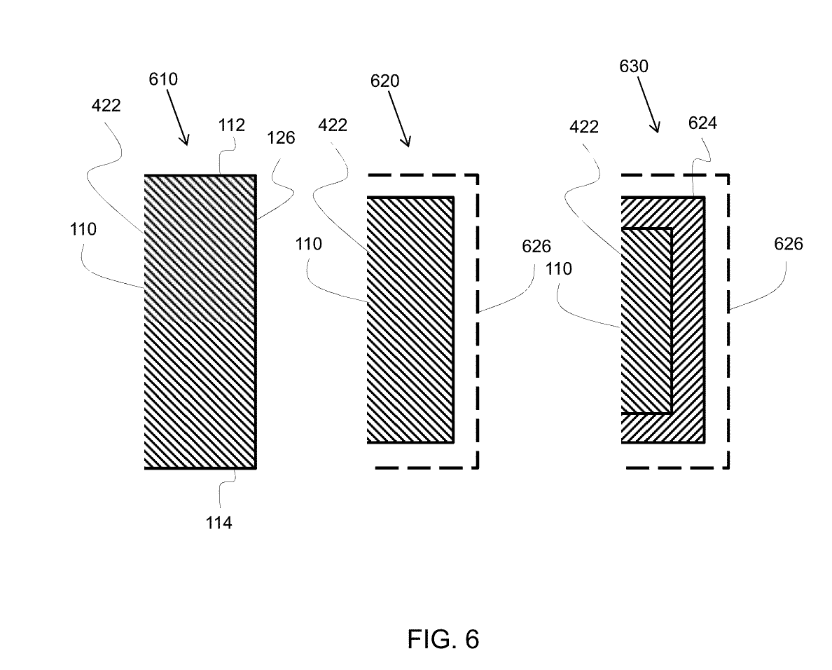

FIG. 5 shows a flowchart for a process in accordance with some embodiments. First, a substrate is prepared for metallization in process flow 510. Then, the substrate may optionally be metallized in process flow 350. FIG. 6 illustrates what the substrate looks like during process flow 510. Specifically, FIG. 6 shows region 400 of FIG. 1. Although FIG. 6 shows a specific substrate geometry, any substrate geometry for which metallization is desired may be used.

Process flow 510 shows steps for preparing substrate 110 for metallization. Schematic 610 shows substrate 110 prior to leaching and/or etching. Region 422, which is the whole substrate in schematic 410, has the bulk composition of substrate 110.

In step 520, substrate 110 is etched. As illustrated in FIG. 6, first surface 112, second surface 114 and interior surface 126 are exposed to etchant and etched. Schematic 620 shows substrate 110 after etching. A part substrate 110 has been removed by etching. Dotted line 626 shows the extent of substrate 110 prior to etching. Substrate 110 is illustrated as being smaller in schematic 620 than schematic 610, because etching primarily results in the removal of a layer as opposed to modifying the composition of substrate 110. Region 422, which is the whole remaining substrate in schematic 620, has the bulk composition of substrate 110

In step 540, substrate 110 is leached after having been etched in step 320. Leaching is expected to form a nanoporous leached layer in an etched surface, just as it does in an un-etched surface. Schematic 630 shows substrate 110 after leaching. A leached layer 624 has been formed due to leaching. Region 422, which has the bulk composition of substrate 110, has correspondingly shrunk. As will become clear from the examples, there is a small part of region 422 next to leached layer 624 that has been subject to some leaching, but not enough to qualify as a “leached layer” as defined herein. Substrate 110 is illustrated as having about the same size in schematic 410 and schematic 420, because leaching primarily removes material from within leached layer 424 to modify the substrate composition, while leaving the shape and size of substrate 110 relatively the same.

In some embodiments, where a substrate is subject to etching followed by leaching before being metallized, after etching and leaching the substrate has a surface roughness Ra of 0.1 nm, 0.2 nm, 0.3 nm, 0.4 nm, 0.5 nm, 0.6 nm, 0.7 nm, 0.8 nm, 0.9 nm, 1.0 nm, or any range having any two of these values as endpoints, or any open-ended range having any of these values as a lower bound. In some embodiments, after etching and leaching the substrate has a surface roughness of 0.4 nm or more, 0.4 nm to 1.0 nm, 0.5 nm or more, 0.5 nm to 1.0 nm, or 1 nm or more.

In some embodiments, where a substrate is subject to etching followed by leaching before being metallized, after etching and leaching the substrate has a leached layer with a thickness of 1 nm, 5 nm, 10 nm, 20 nm, 40 nm, 50 nm, 60 nm, 80 nm, 100 nm, 150 nm, 200 nm, or any range having any two of these values as endpoints, or any open-ended range having any of these values as a lower bound. In some embodiments, the leached layer has a thickness of 20 nm or more, 20 nm to 200 nm, 50 nm or more, or 50 nm to 200 nm.

In some embodiments, where a substrate is subject to etching followed by leaching before being metallized, after etching and leaching the substrate has any of the ranges described above for surface roughness Ra combined with any of the ranges described above for leached layer thickness. In some embodiments, after etching and leaching the substrate has a surface roughness of 0.4 nm or more, 0.4 nm to 1.0 nm, 0.5 nm or more, 0.5 nm to 1.0 nm, or 1 nm or more, combined with a thickness of 20 nm or more, 20 nm to 200 nm, 50 nm or more, or 50 nm to 200 nm.

After etching followed by leaching, substrate 110 may optionally be metallized by any suitable method. One such method is illustrated in FIG. 5.

### Metallizing

After being leached, leached and then etched, or etched and then leached, substrate 110 may optionally be metallized. Any suitable metallization process may be used. Solution or gas based deposition methods that allow copper to penetrate into the leached layer are preferred.

In some embodiments, electroless deposition is used to deposit copper. Before depositing metal by electroless deposition, the substrate is treated with aminosilanes or nitrogen containing polycations, and a catalyst is deposited. The treatment with aminosilanes or nitrogen containing polycations produces a cationic charge state of the glass surface, which enhances catalyst adsorption. The catalyst adsorption step entails treatment of the glass surface with K₂PdCl₄ or ionic palladium or Sn/Pd colloidal solutions. The palladium complexes usually exist in anionic form and, therefore, their adsorption on the glass surface is enhanced by the cationic surface groups such as protonated amines. If K₂PdCl₄ or ionic palladium chemistries are used, the next step involved reduction of the palladium complex into metallic palladium, Pd(0), preferably (but not limited to) in the form of colloids of dimension ˜2-10 nm. If Sn/Pd colloidal solution is used, the palladium is already in Pd(0) form with a Sn shell around it which is removed by acid etching.

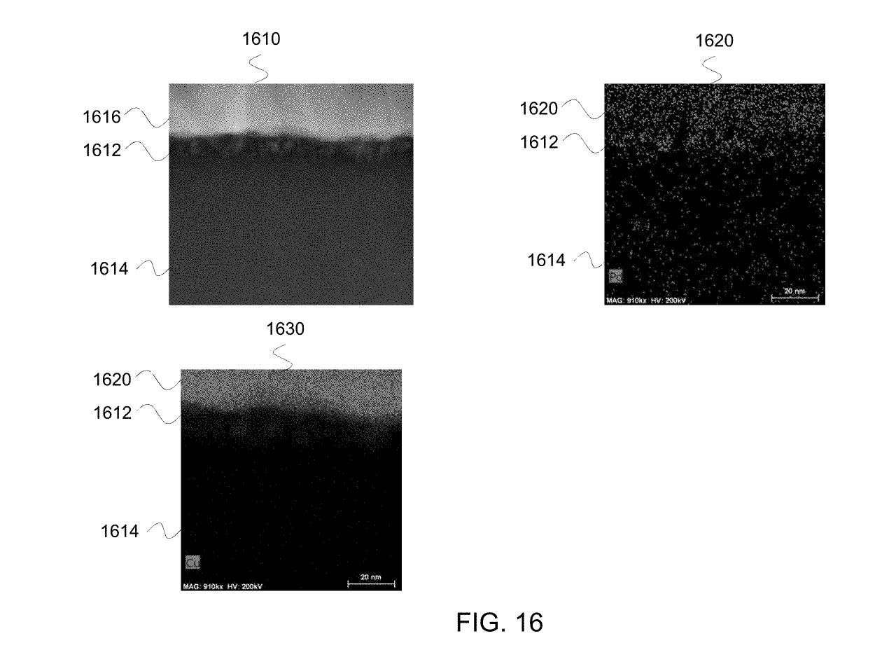

Copper deposits by electroless deposition at a much faster rate where a catalyst is present. Adsorbing catalyst inside the nanoporous structure as well as on the rough surface allows electroless deposition of copper inside the nanoporous structure. Such deposition allows for a much higher degree of mechanical interlocking than would be obtained, for example, with copper deposition on a rough surface without a nanoporous layer, or copper deposition on a rough surface with a nanoporous layer where catalyst was not adsorbed throughout the nanoporous layer. FIG. 7 shows the mechanical interlocking of copper with glass that can be achieved by using a nanoporous layer having catalyst adsorbed throughout. FIG. 16 shows EDS images proving that Pd and Cu are deposited inside a nanoporous layer.

Process flow 350 of FIG. 3 and FIG. 5 illustrates one way to metallize substrate 110. In process flow 350, the following steps are performed in order:

Step 360: charge the nanoporous layer by treating with aminosilanes or nitrogen-containing polycations;
Step 380: after charging, adsorb palladium complexes into the nanoporous layer by treatment with a palladium-containing solution;
Step 390: after adsorbing, deposit electroless copper into the nanoporous layer, for example, a nanoporous layer formed on interior surface 126 of via 124.

FIG. 7 illustrates what substrate 110 looks like during process flow 350. Schematic 710 shows a portion of leached layer 424, for example, after step 380. Pd⁰ colloids 714 have penetrated into nano-pore 712. Schematic 720 shows the portion of leached layer 424 after step 390. Electroless copper 722 has filled nano-pore 712.

In some embodiments, if a thicker copper layer is desired, electroless deposition may optionally be followed by electroplating. Electroless deposition has certain advantages, such as the ability to deposit onto an initially non-conductive surface. But, electroless plating can be slow where thick layers are desired. Once an initial layer of electroless copper is deposited to form the conductive surface used in electroplating, electroplating may be used to more quickly deposit a thicker layer of copper.

### Annealing

After electroless deposition of copper, the samples were annealed at 350° C. for 30 minutes. As described below, the samples were tested for adhesion both before and after annealing. Some samples exhibited superior adhesion prior to annealing. But, avoiding exposure to temperatures similar to the annealing temperature may not be practical, as many applications for copper adhered to glass involve processing at elevated temperatures after the copper is deposited. In addition, annealing relieves stress in the copper, which might, if not relieved, lead to cracking and/or delamination.

### Adhesion

Adhesion tests were performed on copper layers deposited as described herein. A tape test may be used to assess the strength of the bond between the conductive metal and first surface 112 of the metal oxide substrate 110. The tape test may be conducted according to ASTM 3359 using a tape having a specific adhesion strength when bonded to the conductive metal. In some embodiments, the tape test may be conducted on a conductive metal that is copper, and the tape used may have a bond strength to copper of 3 N/cm.

Samples were tested after electroless deposition of copper without annealing. For those samples that passed the pre-anneal adhesion test, a similar sample was annealed at 350° C. for 30 minutes and tested again for adhesion. While the samples tested for adhesion were planar, and the copper was not deposited on the interior surface of a via, the tests are indicative of copper adhesion to the interior surface of a via.

### Comparison

Leaching of high-silicon content multi-component glass, such as alkaline earth boro-aluminosilicate glasses with 51% or more SiO₂ content, by HCl selectively removes the non-SiO₂ components (such as alumina, magnesia etc.) leaving behind a nanoporous surface layer with interconnected geometry. However, the roughness after leaching alone is usually low. On the other hand, etching with HF+HCl selectively removes silicon leaving behind the other metal oxides. While the etchant itself does not necessarily remove the other metal oxides, they do not have sufficient structural integrity to remain once the SiO₂ is etched, so the etching process effectively removes these other metal oxides in addition to SiO₂. So, etching alone usually leads to high surface roughness but no nanoporous layer. A combination of leaching followed by etching achieves both high surface roughness and interconnected porosity. Surprisingly, the surface roughness observed with leaching followed by etching is significantly higher than the surface roughness observed with etching alone. And, with proper control of etching parameters, a leached layer still remains after leaching followed by etching.

Leaching of glass creates nanoporous surface layer with rougher surface, but the increase in roughness is limited. The nano-porosity could provide extra mechanical interlock in addition to surface roughness. On the other hand etching-only of glass could roughen the surface but couldn't generate nanoporous layer.

Leaching, etching, leaching followed by etching, and etching followed by leaching each lead to different and unique microstructures. Leaching alone results in a nanoporous leached layer and a relatively low surface roughness. Etching alone results in a relatively high surface roughness, but no nanoporous leached layer. Etching followed by leaching leads to a surface roughness comparable to that of etching alone, combined with a nanoporous layer. Leaching followed by etching leads to a surface roughness higher than that obtained by etching alone, combined with a nanoporous layer. Without being limited by theory, it is believed that the presence of the leached layer during etching changes the way the etchant interacts with the glass substrate, leading to a higher surface roughness due to etching. The microstructure generated by leaching followed by etching provides better mechanical interlocking and thus increased adhesion between copper and glass surface.

Different chemistries were explored for etching and leaching the glass composition tested herein. The chemistries are described in Table 1:

TABLE 1

| | Type of chemical | | Nanoporous | |
|---|---|---|---|---|
| | treatment | Chemistry | layer | Roughness |
| (1) | Etching | HF or HF-HCl or HF-H₂SO₄ or | No | Medium |
| | | TMAH or NaOH or KOH or | | |
| | | NH₄OH, etc. | | |
| (2) | Leaching | HCl or H₂SO₄ or HNO₃ | Yes | Low to |
| | | | | Medium |
| (3) | Leaching followed by | HCl followed by TMAH or HCl | Yes | Medium to |
| | Etching | followed by NH₄OH | | High |
| (4) | Etching followed by | HF followed by HCl; TMAH | Yes | Medium |
| | Leaching | followed by HNO₃ | | |

### EXPERIMENTAL

As described in the examples below, a variety of glass samples were subject to different etching and/or leaching treatments. The glass described and tested in the examples herein was Corning® Eagle XG glass, which met the criteria of composition 1. Basic testing for leaching was also performed on Corning® Gorilla® Glass, and Corning® Lotus™ Glass, which were observed to form nanoporous layers upon exposure to leaching chemistry.

### Example 1: Substrate Catalyzation, Copper Deposition, and Adhesion Test

After etching and/or leaching, the glass samples described below were treated with 1.0 vol % APTES (aminopropyltriethoxysilane) solution (95 mL methanol, 4 mL H2O and 1 mL APTES) for 15 minutes followed by baking in a 120° C. oven for 30 minutes. Afterwards, K₂PdCl₄ or ionic palladium chemistries were used followed by reduction of the palladium complex into metallic palladium by DMAB (dimethylaminoborane) to create catalyzed substrates. Unless otherwise specified, an ionic palladium chemistry was used in the examples described herein. Then, the catalyzed substrates were coated with a thin copper layer with a thickness of 100-200 nm by electroless plating, followed by a thick copper layer with a thickness of >1 um by electrolytic plating.

The samples were then annealed at 350° C. for 30 minutes. Depending on the sample, tape tests with an adhesion force of 3 N/cm were conducted before and/or after annealing.

### Example 2: Etching ONLY

Separate 6″ glass wafers (a type of substrate) were treated with (a) no etchant (sample 2a); (b) a weak echant, 5% TMAH (tetramethylammonium hydroxide) solution at 60 C for 10 min (sample 2b); and (c) a strong etchant, 0.1M HF solution mixed with 2M HCl at room temperature for 30 min (sample 2c).

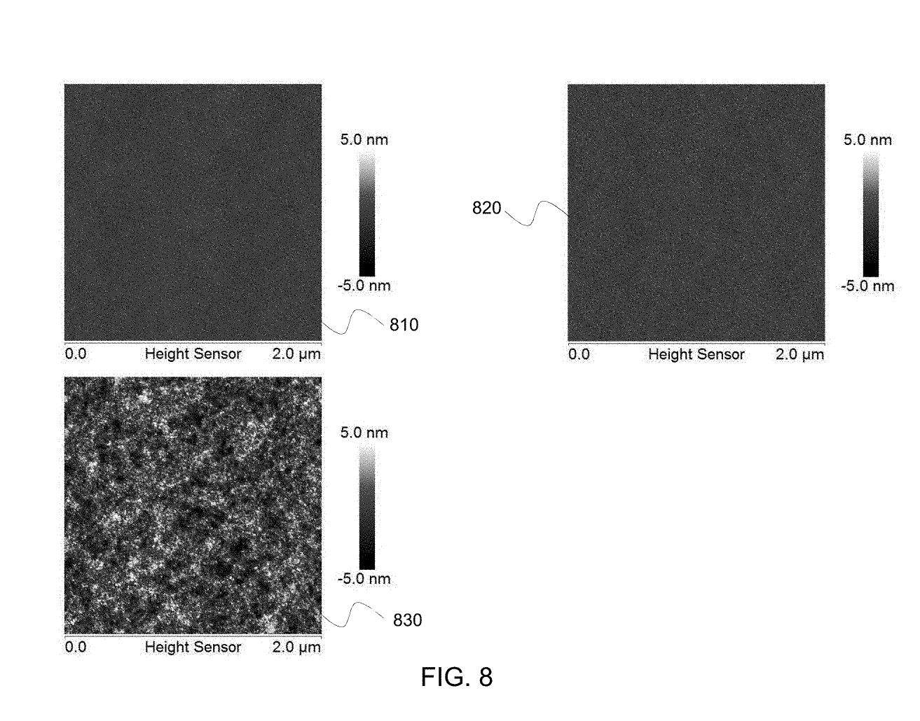

FIG. 8 shows an AFM surface morphology comparing a control sample 2a (image 810), weakly etched sample 2b (image 820) and strongly etched sample 2c (image 830). Sample 2c, etched by strong etchant HF—HCl, shows a clearly rougher surface. Control sample 2a was not etched. Weakly etched sample 2b was etched with 5% TMAH at 60° C. for 10 minutes. Strongly etched sample 3c was etched with 0.1M HF-2M HCl solution at 20° C. for 30 minutes. The surface roughness Ra values are 0.31, 0.37, and 1.41 nm, for sample 2a (control), sample 2b (etched by TMAH), and sample 2c (etched by HF—HCl), respectively. The water contact angle measurement showed that after etching, the water contact angle was reduced from 10 degrees for the sample 2a to around 5 degrees for samples 2b and 2c.

Samples 2a, 2b and 2c were then catalyzed with K₂PdCl₄ chemistry, and copper was deposited, as described in Example 1.

After electroless plating, a full coverage copper was formed on control sample 2a and TMAH-etched sample 2b. HF—HCl etched sample 2c showed some copper delamination issues. After electroplating 2.5 um copper films, TMAH-etched sample 2b failed the 3N/cm tape test before annealing. Control sample 2a passed the tape test prior to annealing, but failed the tape test (3N/cm) after annealing at 350° C. for 30 minutes.

### Example 3: Leaching ONLY (at 75° C.)

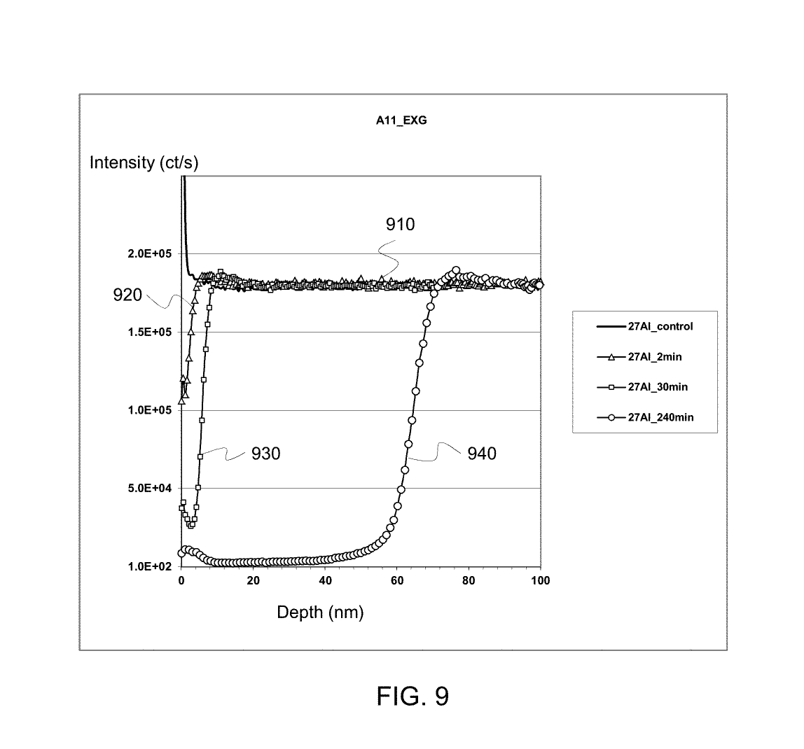

6″ glass wafers were leached with a 0.15M HCl solution at 75° C. for periods ranging from 2 to 1080 minutes. Dynamic SIMS analysis indicated an aluminum depleted surface layer in each of the leached samples. The thickness of this aluminum depleted surface layer increased with leaching time. FIG. 9 shows the results of the SIMS analysis for samples leached for 0 minutes (control sample 3a, plot 910), 2 minutes (sample 3b, plot 920), 30 minutes (sample 3c, plot 930) and 240 minutes (sample 3d, plot 940). Table 2 lists the thickness of the leached layer for the leached samples, where the leached layer is defined as the layer in which aluminum concentration is 50% or less compared to the bulk composition. It can be seen that the leaching layer thickness increased from 1 nm to 409 nm with increasing leaching time from 2 to 1080 minutes.

TABLE 2
Leach layer thickness and roughness of the glass samples
that were leached under different conditions.

| | | | | Thickness | |
|---|---|---|---|---|---|
| | HCl | Leaching | Leaching | of leach | Ra (nm) |
| Sample | conc. | temp. | time | layer (nm) by | (500 nm × |
| code | (M) | (° C.) | (min) | SIMS | 500 nm) |
| 3a (control) | | | | | 0.30 |
| 3b | 0.15 | 75 | 2 | 1 | 0.33 |
| 3c | 0.15 | 75 | 30 | 5 | 0.35 |
| 3d | 0.15 | 75 | 240 | 64 | 0.45 |
| 3e | 0.15 | 75 | 1080 | 409 | 0.36 |

BET surface analysis indicates that the leach layer is nanoporous. For example, the sample 3e that was leached for 1080 minutes had a nanoporous layer with the BJH average pore diameter of 7.16 nm.

Table 2 also compares the roughness of the control and leached samples, which was measured by AFM at a resolution of 500 nm×500 nm. It can be seen that leaching can roughen the glass surface to some extent. The surface roughness was increased from 0.33 to 0.45 nm as leaching time increased from 2 to 240 minutes. Further extending leaching time did not increase roughness.

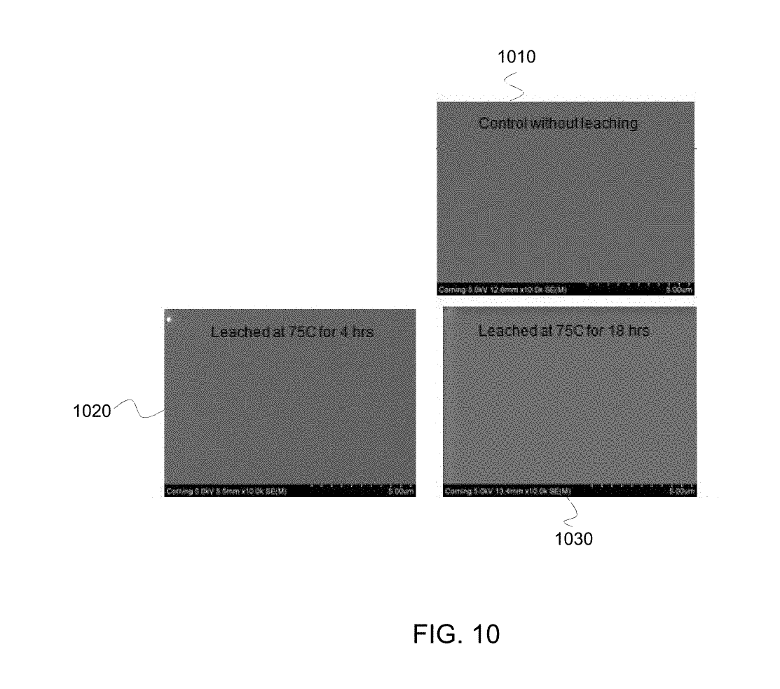

FIG. 10 shows SEM images at 10,000x of surface morphology for unleached control sample 3a (image 1010) and leached samples 3d (image 1020) and 3e (image 1030).

These SEM images were indistinguishable for samples 3a, 3d and 3e.

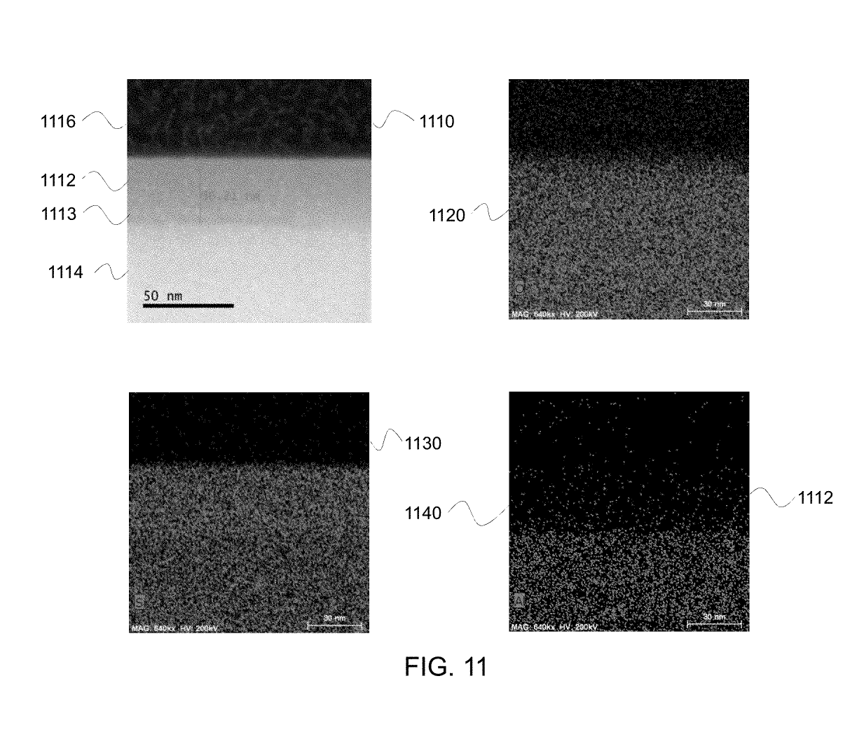

For electroless plating and copper-to-glass adhesion evaluation, 6″ glass wafers were leached with 0.15M HCl solution at 75° C. for 2 hours. FIG. 11 shows an SEM/EDS analysis for one of these wafers prior to catalyzation and copper deposition. Image 1110 shows a cross-sectional SEM image of that wafer. Image 1120 shows an EDS oxygen map of the same sample. Image 1130 shows an EDS silicon map of the same sample. Image 1140 shows an EDS aluminum map of the same sample.

As shown in FIG. 11, a leached layer 1112 is visible in both image 1110 and 1140. Layer 1114 is the bulk glass, which has the bulk composition. Region 1116 is the outer surface of the sample, and is not a part of the cross section. The SIMS data for aluminum, illustrated in image 1140, shows a leached layer depth of 23 nm, as defined by aluminum concentration 50% or less compared to the bulk composition. In image 1110, a layer 1113 is visible beneath leached layer 1112, where the thickness of leached layer 1112 plus layer 1113 is 36 nm. In layer 1113, there has been leaching sufficient to make layer 1113 appear similar to leached layer 1112, but not enough leaching to cross the threshold of 50% depletion of Al. Also, the EDS maps shown in FIG. 11, image 1120, image 1130 and image 1140, indicate that the leached layer is a silica-enriched layer with depletion of aluminum and other elements.

A layer described as “silica enriched” does not necessarily mean that silica has been added to the layer. Rather, the “silica enriched” layer has a silica content higher than that of the bulk composition. This higher silica content may be due to preferential removal of components other than silica.

The 6″ glass wafers leached with 0.15M HCl solution at 75° C. for 2 hours were then catalyzed with K₂PdCl₄ chemistry, and copper was deposited as described in Example 1. After electroless plating, a full coverage uniform copper was formed. After electroplating to form the 2.5 um copper film, these samples passed the 3N/cm tape test, but failed after annealing at 350° C. for 30 minutes.

### Example 4: Leaching ONLY (at 95° C.)

Another leaching experiment was done on 2″×2″ glass coupons with 0.15M HCl solution at 95° C. for 6 hours. FIG. 12 shows a Dynamic SIMS profile for five elements (B, Mg, Al, Si, and Ca) of this glass sample. FIG. 12 shows a silica-enriched layer formed on the surface with other elements such as aluminum, calcium, magnesium and boron depleted. The leached layer thickness was 237 nm, based on Al₂O₃ content.

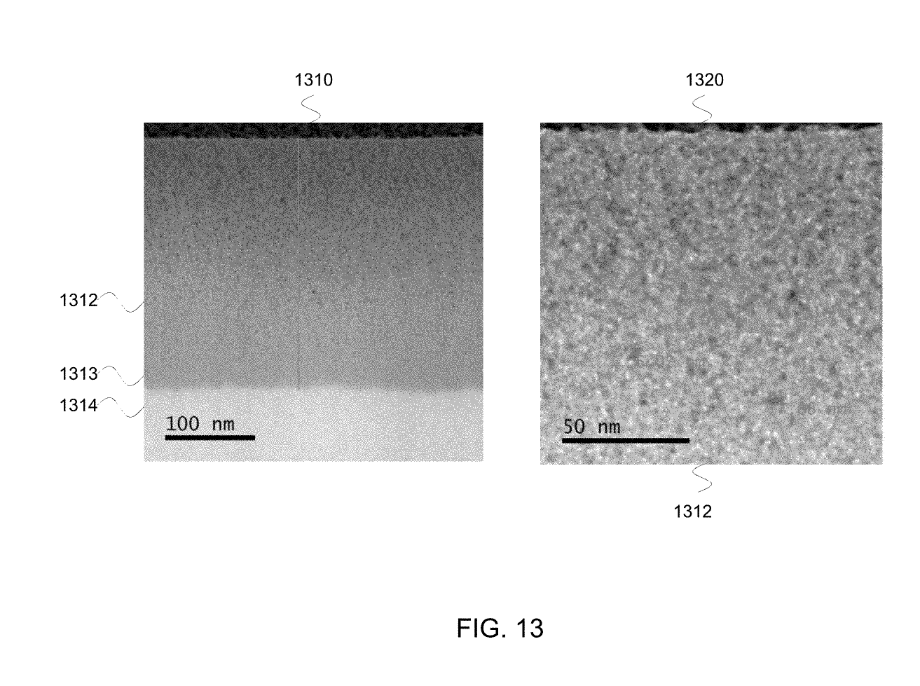

FIG. 13 shows cross-sectional SEM images of the leached sample of Example 4. Image 1320 is at a higher resolution than image 1310. The following layers are present in image 1310: leached layer 1312; a layer 1313 that has enough leaching to appear similar to leached layer 1312, but not enough to meet the 50% depletion criteria for a leached layer; and a layer 1314 with the bulk composition. The thickness of leached layer 1312 plus layer 1313 is 279 nm, which is higher than the 237 nm measured by dynamic SIMS analysis due to the presence of layer 1313.

Image 1320 shows only leached layer 1312. Based on image 1320, the pore size is in the range of 2-8 nm. The surface SEM with ×10,000 didn't distinguish the difference of the surface morphology of the control sample without leaching and the leached sample. The surface roughness Ra of the leached samples was measured to be 0.36 nm by AFM.

For electroless plating and copper-to-glass adhesion evaluation, the 2″×2″ glass coupons of Example 4 were leached with 0.15M HCl solution at 95° C. for 6 hours, followed by electroless plating of a thin copper film (100-200 nm in thickness) and electroplating of thick copper film (2.5-5 um in thickness). The leaching solution used in Example 4 during evaluation of electroless plating and copper-to-glass adhesion was slightly different from that used for the SIMS profile, but is expected to work the same. The sample passed 3 N/cm tape test both before annealing and after annealing at 350° C. for 30 minutes.

### Example 5: Leaching Followed by Weak Etching

In Example 5, the glass was first leached. Then, the glass was etched with a weak etchant with temperature and time controlled such that only a part of the leached layer was removed. This treatment surprisingly enables glass having a nanoporous layer with more open surface microstructure and a rougher surface compared to the leaching-only treatment and the etching-only treatment. This surface microstructure and roughness provides better mechanical interlocking and thus increased adhesion between copper and glass surface.

6 sets of 2″×2″ glass coupons were leached with 0.15 M HCl solution at 95° C. for 6 hrs, followed by etching with 5% TMAH solution for varied temperatures and etching times. The etching conditions and the resulting leached layer thicknesses and surface roughness for each sample are listed in Table 3. All of the samples had nanoporous leached layers remaining after etching, with leached layer thickness decreasing at higher etching temperatures and longer etching times. Surprisingly, it was found that the surface roughness of samples that were leached then etched was significantly higher than samples that were etched under the same conditions, but without any leaching. This difference was particularly marked for higher etching temperatures, e.g. 60° C.

TABLE 3
Thickness of leach layer of the samples
that were leached with 0.15M HCl at 95° C. for 6 hrs

| | | | Thickness of | |
|---|---|---|---|---|
| | | | leach layer (nm) | |
| | | | by SIMS (based | |
| | Etching | Etching | on Al | Roughness Ra |
| Sample | temp. (° C.) | time (min) | concentration) | (2 μm × 2 μm) |
| 5a | 40 | 10 | 192 | 0.46 |
| 5b | 40 | 30 | 174 | 1.37 |
| 5c | 60 | 0.5 | 188 | 0.52 |
| 5d | 60 | 2 | 160 | 0.79 |
| 5e | 60 | 10 | 63 | 2.60 |
| 5f | 60 | 30 | 22 | 2.51 |

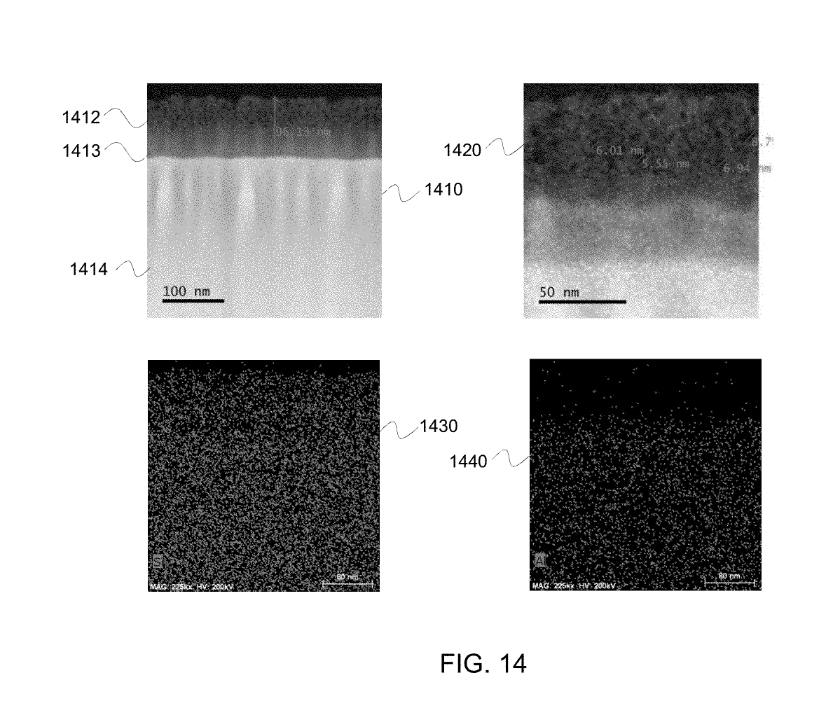

FIG. 14 shows cross-sectional SEM images and EDS maps of sample 5e, which was leached with 0.15 M HCl at 95° C. for 6 hrs, and then TMAH etched at 60° C. for 10 minutes. Image 1410 is an SEM image. As with FIGS. 11 and 13, leached layer 1412, layer 1413 having some leaching but not enough to meet the depletion criteria for a leached layer, and layer 1414 having the bulk composition are visible. The total thickness of leached layer 1412 and layer 1413 was 96 nm. Image 1420 is in SEM image at a higher resolution than image 1410. A pore size in the range 5-9 nm can be seen in image 1420. Image 1430 is an EDS silicon map, showing no Si depletion in the leached layer. Image 1440 is an EDS aluminum map, showing an Al-depleted region corresponding to the leached layer.

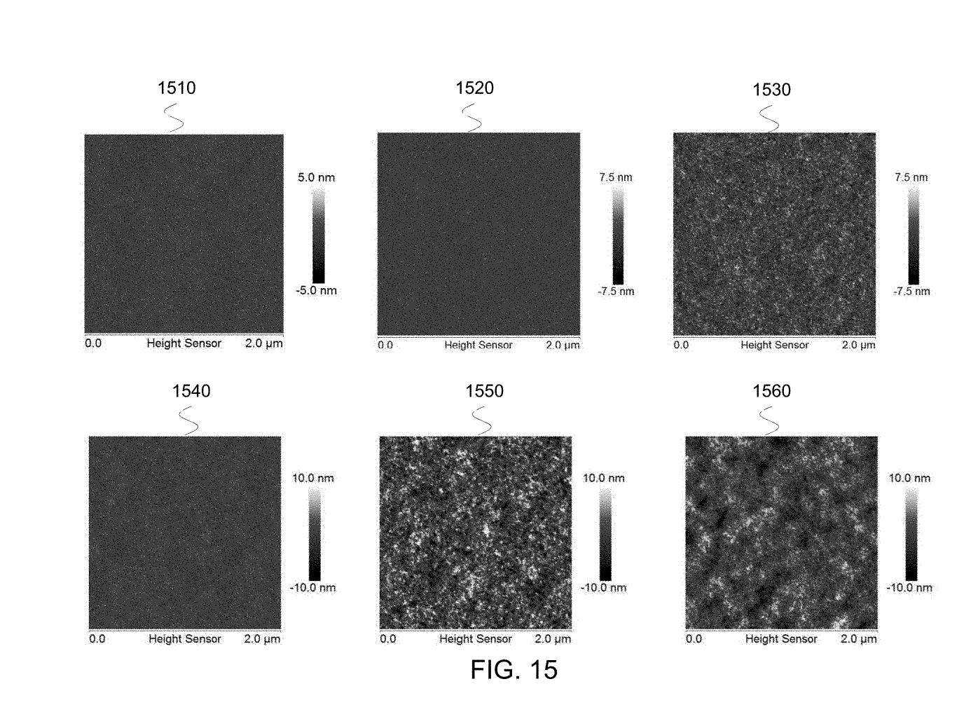

FIG. 15 shows AFM images for six samples not leached or etched, just leached, or leached and etched. Where a sample was leached, the leaching was with 0.15 M HCl at 95° C. for 6 hrs:
Image 1510, a control sample, without leaching or etching;
Image 1520, leached, no etching;
Image 1530, sample 5b, leached followed by TMAH etching at 40° C. for 30 minutes;
Image 1540, sample 5d, leached followed by TMAH etching at 60° C. for 2 minutes;
Image 1550, sample 5e, leached followed by TMAH etching at 60° C. for 10 minutes;
Image 1560, sample 5f, leached followed by TMAH etching at 60° C. for 30 minutes.

The combination of leaching and etching led to the roughest surfaces with more open microstructure. Without being limited by any theories, it is believed that the nanoporous structure is prone to non-uniform etching, which increases post-etch surface roughness of nano-porous structures as compared to non-porous structures. In addition, it is believed that leaching results in an internal leach layer having a relatively open porous microstructure, covered by an external leach layer having a less open porous microstructure due to solution collapse of the porous network caused by the drying. Etching can remove this external leach layer, exposing the internal leach layer with its more open porous microstructure.

Electroless plating and copper-to-glass adhesion evaluation was conducted on 4 samples that were leached with 0.15M HCl at 95° C. for 6 hours followed by 5% TMAH etching at 60° C. for 2, 10, 20, and 30 minutes, respectively. The same procedure was applied to all four samples: electroless plating of a thin copper film (100-200 nm in thickness) followed by electroplating of thick copper film (2.5-5 um in thickness). All four samples passed 3N/cm tape test before annealing. After annealing at 350° C. for 30 minutes, the sample with 2 min-TMAH etching failed, and the other three samples passed 3 N/cm tape test.

FIG. 16 shows TEM/EDS images of cross-section of the sample leached and TMAH-etched for 30 minutes which had a sandwich structure, with a nanoporous leached layer 1612 between copper film 1616 and bulk glass layer 1614. Image 1610 is a TEM image. Image 1620 is an EDS Pd map. Image 1630 is an EDS Cu map. Image 1620 and image 1630 demonstrate the presence of Pd and Cu, respectively, inside the leached layer. Color images corresponding to images 1620 and 1630 show the presence of Pd and Cu more clearly. The porosity of the leached layer in combination with cationic surface treatment led to a high concentration of palladium catalyst on the outer surface of leached layer 1612, as well as mechanical interlocking as schematically shown in FIG. 7, schematic 710. Subsequently, electroless copper was deposited into the nanoporous surface layer. This led to good mechanical interlocking of the copper as shown in FIG. 7, schematic 720.

### CONCLUSION

Those skilled in the relevant art will recognize and appreciate that many changes can be made to the various embodiments described herein, while still obtaining the beneficial results. It will also be apparent that some of the desired benefits of the present embodiments can be obtained by selecting some of the features without utilizing other features. Accordingly, those who work in the art will recognize that many modifications and adaptations are possible and can even be desirable in certain circumstances and are a part of the present disclosure. Therefore, it is to be understood that this disclosure is not limited to the specific compositions, articles, devices, and methods disclosed unless otherwise specified. It is also to be understood that the terminology used herein is for the purpose of describing particular embodiments only and is not intended to be limiting. Features shown in the drawing are illustrative of selected embodiments of the present description and are not necessarily depicted in proper scale. These drawing features are exemplary, and are not intended to be limiting.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or description that the steps are to be limited to a specific order, it is no way intended that any particular order be inferred.

Unless otherwise expressly stated, percentages of glass components described herein are in mol % on an oxide basis.

When referring to a percentage of a percentage herein, the percentages should be multiplied and not added or subtracted. For example, if a quantity is “50% or less than X,” where X is 80%, the quantity is 40% or less. The “50%” of “80%” results in 40% (80%×50%), not 30% (80%-50%).

It will be apparent to those skilled in the art that various modifications and variations can be made without departing from the spirit or scope of the illustrated embodiments. Since modifications, combinations, sub-combinations and variations of the disclosed embodiments that incorporate the spirit and substance of the illustrated embodiments may occur to persons skilled in the art, the description should be construed to include everything within the scope of the appended claims and their equivalents.

What is claimed is:

1. A method, comprising:
leaching a surface of a glass or glass ceramic substrate to form a leached layer;
wherein:
the glass or glass ceramic substrate comprises a multi-component material, the material having a bulk composition, in mol % on an oxide basis:
51% to 90% SiO₂;
10% to 49% total of minority components ROₓ; and
wherein leaching comprises selectively removing components ROₓ of the glass or glass ceramic substrate preferentially to removal of SiO₂;
wherein, in the leached layer, the ROₓ concentration is 50% or less than the ROₓ concentration of the bulk composition.

2. The method of claim 1, further comprising:
etching the surface;
wherein:
etching comprises selectively removing SiO₂ from the substrate preferentially to removal of minority components ROₓ.

3. The method of claim 2, wherein:
leaching the surface is performed before etching the surface.

4. The method of claim 2, wherein:
leaching the surface is performed after etching the surface.

5. The method of claim 1, wherein:
after leaching, the surface has a surface roughness Ra of 0.3 nm or more, and the leached layer has a thickness of 100 nm or more.

6. The method of claim 2, wherein:
after leaching and etching, the surface has a surface roughness Ra of 0.4 nm or more, and the leached layer has a thickness of 20 nm or more.

7. The method of claim 2, wherein:
after leaching and etching, the surface has a surface roughness Ra of 0.5 nm or more, and the leached layer has a thickness of 20 nm or more.

8. The method of claim 1, wherein:
the leached layer has a thickness of 20 nm or more.

9. The method of claim 1, wherein:
the leached layer is nanoporous layer.

10. The method of claim 9, wherein:
the nanoporous layer comprises pores having a size of 2-8 nm.

11. The method of claim 1, wherein:
the leached layer has a re-entrant geometry.

12. The method of claim 1, wherein the surface is an interior surface of a via formed in the glass or glass ceramic substrate.

13. The method of claim 1, further comprising:
depositing electroless copper onto the surface;
depositing electroplated copper over the electroless copper.

14. The method of claim 13, further comprising:
charging the leached layer by treating with aminosilanes or nitrogen-containing polycations; and
after charging, adsorbing palladium complexes into the leached layer by treatment with a palladium-containing solution;
wherein depositing electroless copper into the leached layer and onto the surface occurs after adsorbing.

15. The method of claim 13:
wherein the electroplated copper is capable of passing a 3N/cm tape test after being annealed at 350° C. for 30 minutes.

16. The method of claim 1, wherein ROₓ is selected from Al₂O₃, B₂O₃, MgO, CaO, SrO, BaO, and combinations thereof.

17. The method of claim 1, wherein the material has a bulk composition, in mol % on an oxide basis:
SiO₂: 64.0-71.0
Al₂O₃: 9.0-12.0
B₂O₃: 7.0-12.0
MgO: 1.0-3.0
CaO: 6.0-11.5
SrO: 0-2.0
BaO: 0-0.1.

18. The method of claim 1, wherein leeching comprises exposing the surface to a solution consisting essentially of hydrochloric acid, sulfuric acid, nitric acid and combinations thereof.

19. The method of claim 2, wherein etching comprises exposing the surface to an etchant selected from: a solution comprising hydrofluoric acid and hydrochloric acid, and a solution comprising TMAH.

20. An article, comprising:
a glass or glass ceramic substrate having a plurality of vias formed therein, each via having an interior surface;
the glass or glass ceramic substrate comprises a multi-component material, the material having a bulk composition, in mol % on an oxide basis:
51% to 90% SiO₂;
10% to 49% total of minority components ROₓ;
a leached layer formed under the interior surfaces of the vias, wherein: in the leached layer, the ROₓ concentration is 50% or less than the ROₓ concentration of the bulk composition; and
the leached layer has a thickness of 1 nm or more.
